(19) United States
(12) Patent Application Publication
(10) Pub. No.: US 2010/0140801 A1
(43) Pub. Date: Jun. 10, 2010

(54) Device

(75) Inventors: Satoshi Anbai, Tokyo (JP); Motoo Washiya, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/591,985

(22) Filed: Dec. 7, 2009

(30) Foreign Application Priority Data
Dec. 10, 2008 (JP) 2008-313909

(51) Int. Cl. H01L 23/498

(52) U.S. Cl. 257/738; 257/777; 257/E23.069; 257/E23.067

(57) ABSTRACT

In a device acting as a semiconductor device, a first chip has a first protective layer pattern while a second chip has a second protective layer pattern which is two-dimensionally symmetrical with the first protective layer pattern to provide a reflection symmetrical relationship between the first and the second protective layer patterns. When the first and the second chips form a back-to-back structure, both the first and the second protective layer patterns are completely superposed with each other.

This application is based upon and claims the benefit of priority from Japanese patent application No. 2008-313909, filed on Dec. 10, 2008, the disclosure of which is incorporated herein in its entirety by reference.

### BACKGROUND OF THE INVENTION

1. Field of the Invention

This invention relates to a device, such as a semiconductor device.

2. Description of Related Art

With the advance of miniaturization and high performance of electronic devices, recent requirements have been directed to miniaturizing and thinning the semiconductor chips used in such electronic devices. As the semiconductor chips become thinner and thinner by grinding a back surface of each semiconductor device, problems tend to be caused to occur such that the semiconductor chips are undesirably warped due to the thin thickness of each semiconductor chip.

Herein, it is to be noted that a semiconductor chip usually has a substrate body of, for example, silicon and a protective film of, for example, resin covered on a surface of the silicon substrate body and that a coefficient of thermal expansion (CTE) of the silicon substrate body is different from that of the protective layer. Such a difference of the CTEs between the silicon substrate body and the protective layer weakens resistance properties of the substrate body against a stress which is caused to occur due to the difference of the CTEs as the substrate body becomes thinner. Thus, the semiconductor chips are warped, as mentioned above.

When the warped semiconductor chips are assembled into packages, each package should have a thickness enough to accommodate such warped semiconductor chips and can not be sufficiently thinned in thickness. This prevents requirements of thinness and results in an increase of costs. Under the circumstances, it is preferable that each semiconductor chip has a structure which can suppress a warp as small as possible even if such a semiconductor chip is thinned.

In Japanese Unexamined Patent Publication No. 2005-150719 (Patent Document D1), disclosure is made about a semiconductor device of a stacked package type, wherein an upper BGA package which encapsulates an upper chip is stacked onto a lower BGA package which encapsulates a lower chip. Each of the upper and the lower chips has an active or front surface on which an integrated circuit is formed and a back surface opposite to the active surface.

In the semiconductor device illustrated in FIG. 2 of the Patent Document D1, the back surface of the lower chip is attached onto the back surface of the upper chip via an adhesive. Herein, this structure might be called a back-to-back structure for brevity of description. In addition, the lower BGA package is bonded onto a first substrate while the upper BGA package is bonded onto a second substrate. Thus, Patent Document D1 proposes a back-to-back structure of the semiconductor chips which can increase a capacity without widening an area for assembling the lower and the upper chips.

It is to be noted in Patent Document D1 that no consideration is made at all about a difference between patterns of protective layers formed on the lower and the upper chips and about any problem which might be caused to occur due to the difference between the above-mentioned patterns.

In Japanese Unexamined Patent Publication No. 2000-277682 (Patent Document D2), disclosure is also made about a semiconductor device of a CSP (Chip Size Package) type, which has a back-to-back structure. Specifically, the semiconductor device has two semiconductor chips adhered to each other on both back surfaces via an adhesive layer. With this structure, both of active surfaces on which integrated circuits are formed are directed outside of the semiconductor device, together with sealing resin layers.

With this structure, the two semiconductor chips are approximately symmetrical with each other with respect to the adhesive layer when it is seen in a cross section. As a result, such a back-to-back structure can avoid a warp of each of the semiconductor chips. Specifically, the symmetrical structure of the two semiconductor chips with respect to the adhesive layer is shown in Patent Document D2 only on a sectional plane. In this connection, sealing resin regions or protective layers and conductive posts on both the active layers of the two semiconductor chips are arranged on the sectional plane in approximate line symmetry with respect to the adhesive layer.

In the Patent Document D2, the semiconductor device of the back-to-back structure is manufactured by bonding two wafers via the adhesive layer and by dicing the bonded wafers into the semiconductor chips of the back-to-back structure. However, no consideration is made at all in the Patent Document D2 about a two-dimensional structure of each semiconductor chip to be attached to each other.

Herein, it is assumed that the semiconductor chips may have the same structure as each other and are adhered to each other to form the back-to-back structure. In this event, it has been found out that the warp of the semiconductor chips can not completely be avoided even in the above-mentioned back-to-back structure and the protective layers have the same patterns on the two semiconductor chips.

### SUMMARY OF THE INVENTION

This invention seeks to improve a warp of semiconductor chips even if each semiconductor chip becomes thinner and thinner.

In a first embodiment of this invention, there is provided a device, comprising a first chip which has a first front surface, a first back surface opposite to the first front surface, and a first surface pattern provided on the first front surface and a second chip which has a second front surface, a second back surface opposite to the second front surface, and a second surface pattern provided on the second front surface, wherein the first and the second surface patterns two-dimensionally have a reflection symmetrical relationship to each other.

In a second embodiment of this invention, there is provided a semiconductor device, comprising a first chip which has a first front surface, a first back surface opposite to the first front surface, and a first surface pattern provided on the first front surface and a second chip which has a second front surface, a second back surface opposite to the second front surface, and a second surface pattern provided on the second front surface, wherein the first and the second surface patterns two-dimensionally have a reflection symmetrical relationship to each other.

In a third embodiment of this invention, there is provided a method of designing a chip structure formed by a first chip having a first front surface and a first back surface and a second chip which has a second front surface and a second back surface attached to the first back surface of the first chip. The method comprises preparing first pattern data specifying a first surface pattern to be formed on the first front surface, obtaining, from the first pattern data, second pattern data which has a reflection symmetrical relationship with the first pattern data, and forming first and second patterns on the first and the second front surfaces of the first and the second chips, respectively.

### BRIEF DESCRIPTION OF THE DRAWINGS

The above features and advantages of this invention will be more apparent from the following description of certain exemplary embodiments taken in conjunction with the accompanying drawings, in which:

FIG. 1 shows a side view of a device or a chip structure according to a first embodiment of this invention;

FIG. 2 shows a plan view of the device illustrated in FIG. 1 when the chip structure is seen from an arrow A1;

FIG. 3 shows another plan view of the device illustrated in FIG. 1 when it is seen from an arrow A2;

FIG. 4 shows a sectional view of the device illustrated in FIG. 1 when it is sectioned along a line B-B′ in FIG. 2 and a line C-C′ in FIG. 3;

FIG. 5 shows a sectional view of a semiconductor device according to a second embodiment of this invention, which includes the chip structure illustrated in FIGS. 2 to 4;

FIG. 6 shows a sectional view of a semiconductor device according to a third embodiment of this invention, which is featured by a chip structure;

FIG. 7 shows a sectional view of a semiconductor device according to a fourth embodiment of this invention, which includes the chip structure illustrated in FIG. 6;

FIG. 8 shows a sectional view of a semiconductor device according to a fifth embodiment of this invention, which is featured by stacking two chip structures; and

FIG. 9 shows a sectional view of a semiconductor device according to a sixth embodiment of this invention, which includes the stacked chip structure illustrated in FIG. 8.

### DESCRIPTION OF THE EXEMPLARY EMBODIMENTS

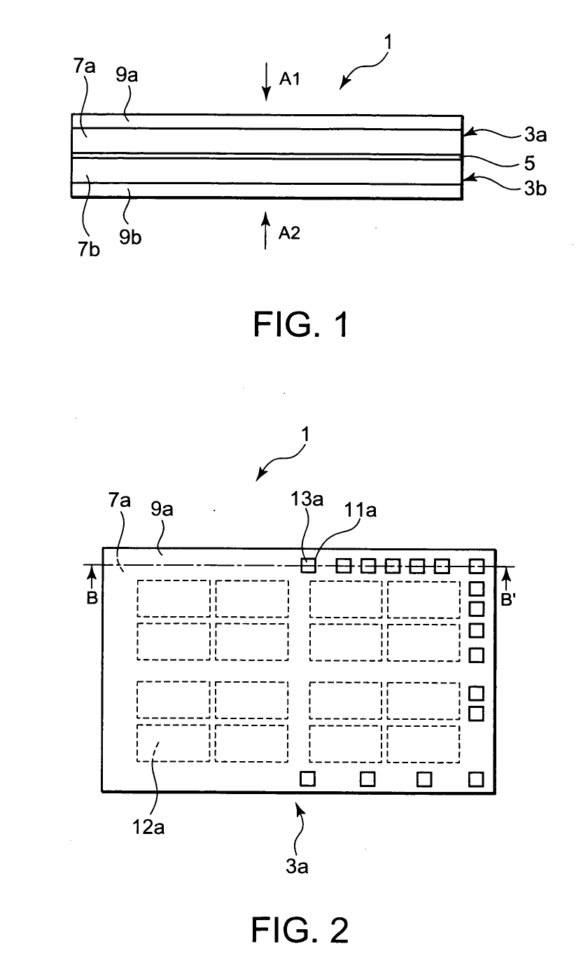

Referring to FIG. 1, a device 1 according to a first embodiment of this invention might be called a chip structure or a semiconductor device and has a first semiconductor chip 3a and a second semiconductor chip 3b each of which may be, for example, a memory, such as DRAM and which might be simply often called first and second chips, respectively. The first semiconductor chip 3a has a first front surface and a first back surface directed upwards and downwards of FIG. 1, respectively, while the second semiconductor chip 3b has a second front surface and second back surface directed downwards and upwards of FIG. 1, respectively.

Although not shown in FIG. 1, the first and the second semiconductor chips 3a and 3b are specified by first and second surface patterns provided on the first and the second front surfaces, respectively, as will become clear as the description proceeds.

Specifically, the first semiconductor chip 3a has a first chip main body (first substrate) 7a which has a first chip or active surface (first side) directed upwards of FIG. 1 and defines the first back surface (second side) directed downwards. A first protective layer 9a is coated on the first chip surface of the first chip main body 7a on which a first semiconductor integrated circuit is formed.

The second semiconductor chip 3b has a second chip main body (second substrate) 7b which has a second front or active surface (third side) directed downwards and a second back surface (fourth side) directed upwards. A second protective layer 9b is coated on the second front surface of the second chip main body 7b on which a second semiconductor integrated circuit.

Herein, it is to be noted that the first surface pattern of the first front surface is defined by the first protective layer 9a while the second surface pattern of the second front surface is defined by the second protective layer 9b.

Each of the first and the second protective layers 9a and 9b may be formed by a synthetic resin, such as polyimide or the like, and have a CTE different from each of the first and the second chip main bodies 7a and 7b.

As illustrated in FIG. 1, the first back surface of the first chip main body 7a (namely, the first chip 3a) is attached to the second back surface of the second chip main body 7b (namely, the second chip 3b) via an adhesive layer 5 of epoxy resin or the like, so as to form a back-to-back structure.

In other words, the first and the second chip main bodies 7a and 7b are adhered to each other via the adhesive layer 5 on the first and the second back surfaces.

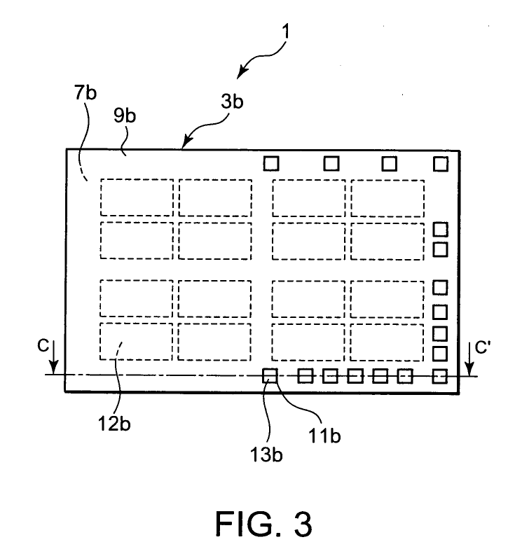

Herein, it is to be noted that the first and the second chips 3a and 3b have two-dimensional arrangements of the first and the second protective layers 9a and 9b, as illustrated in FIGS. 2 and 3, respectively. Specifically, the first chip 3a has the first protective layer 9a of a rectangular shape and the first integrated semiconductor circuits (depicted by 12a) which is formed on the first chip main body 7a and which is shown by broken lines. The illustrated first protective layer 9a is covered on the first integrated semiconductor circuits and is subjected to patterning to form seven bonding patterns (first holes) along an upper side of the first protective layer 9a, to form six bonding patterns (first holes) along a right-hand side of the first protective layer 9a, and to form four bonding patterns (first holes) along a bottom side thereof. The seven bonding patterns along the upper side, the bonding patterns along the right-hand side, and the four boding patterns along the bottom side may be collectively called a first protective layer pattern 11a. Although description will be made about the bonding patterns alone, fuse patterns and the like may be formed in the first protective layer 9a.

As apparent from the bonding patterns illustrated in FIG. 2, the first protective layer pattern 11a of the first protective layer 9a is not symmetrical with respect to a center line of the first chip main body 7a to be drawn at a center between the upper and the bottom sides of the first chip main body 7a.

As shown in FIG. 3, the second chip 3b has the second protective layer 9b of a rectangular shape and the second integrated semiconductor circuits (depicted by 12b) which is formed on the second chip main body 7b and which is shown by broken lines. The illustrated second protective layer 9b is covered on the second integrated semiconductor circuits 12b and is subjected to patterning to form seven bonding patterns (second holes) along a bottom side of the second protective layer 9b, to form six bonding patterns (second holes) along a right-hand side of the second protective layer 9b, and to form four bonding patterns (second holes) along an upper side thereof. Thus, the second protective layer 9b has a second protective layer pattern 11b which is formed by the bonding patterns arranged along the bottom side, the upper side, and the right-hand side of the second protective layer 9b and which is not symmetrical with a center line of the second chip main body 7b to be drawn at a center between the upper and the bottom sides of the second chip main body 7b.

In FIGS. 2 and 3, it is noted that the first protective layer pattern 11a of the first protective layer 9a is not apparently identical with the second protective layer pattern 11b of the second protective layer 9b, as readily understood by comparing FIGS. 2 and 3 with each other. However, it should be aware that the first protective layer pattern 11a has a reflection symmetrical relationship or a mirror symmetry relationship with the second protective layer pattern 11b, as understood by superposing the first back surface of the first chip 3a shown in FIG. 2 onto the second back surface of the second chip 3b shown in FIG. 3.

Thus, it should be noted that such a reflection symmetrical relationship or mirror image relationship enables to provide or realize two-dimensional superposition of the first and the second protective layer patterns 11a and 11b when the first and the second chips 3a and 3b form the back-to-back structure by stacking the second back surface of the second chip 3b onto the first back surface of the first chip 3a.

In the interim, it is assumed that the first protective layer pattern 11a is identical with the second protective layer pattern 11b and does not have any reflection symmetrical relationship. In this event, it should be aware that two dimensional superposition can not be accomplished when the back-to-back structure is formed by the first and the second chips 3a and 3b and when each of the first and the second protective layer patterns 11a and 11b is not any symmetrical pattern with respect to a center line drawn at each center between the upper and the bottom sides of each chip main body 7a and 7b.

Under the circumstances, it has been confirmed that such incomplete superposition due to the same patterns of the first and the second protective layer patterns 11a and 11b brings about a warp of each of the first and the second chips 3a and 3b.

Herein, let the back-to-back structure be formed by stacking the first back surface of the first chip 3a onto the second back surface of the second chip 3b via an adhesive layer 5. Specifically, the first and the second protective layers 9a and 9b which have the first and the second protective layer patterns 11a and 11b specified by the reflection symmetrical relationship are attached to each other via the adhesive layer 5 by stacking the first back surface of the first chip 3a onto the second back surface of the second chip 3b.

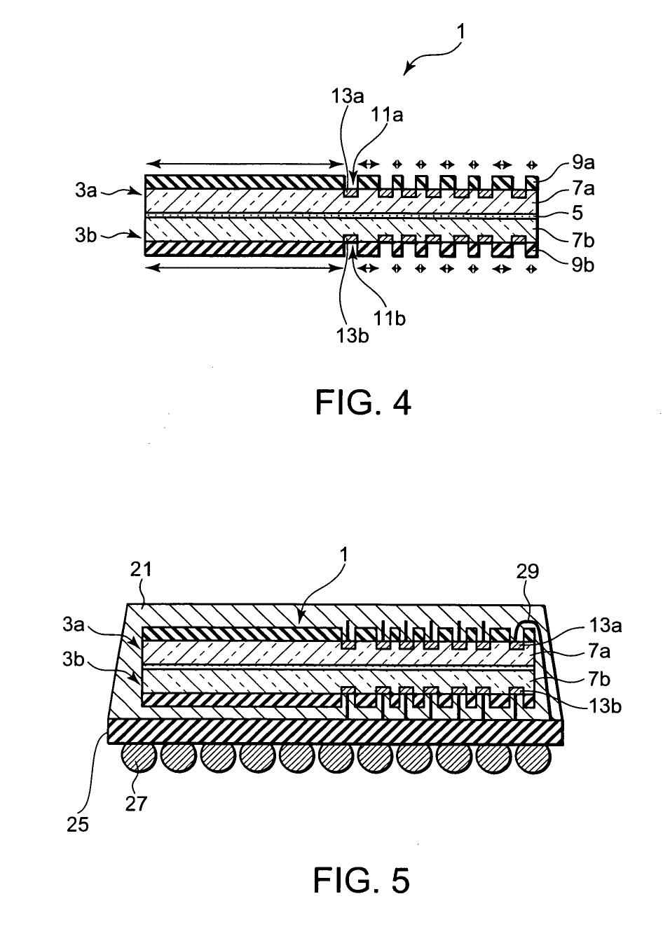

Referring to FIG. 4, the first chip 3a is stacked on the second chip 3b to form the back-to-back structure. In FIG. 4, the back-to-back structure of the first and the second chips 3a and 3b shows a sectional view sectioned or cut away along a line B-B shown in FIG. 2 and along a line C-C shown in FIG. 5. As shown in FIG. 4, the seven bonding patterns along the upper side of the first protective layer pattern 11a illustrated in FIG. 2 are completely or two-dimensionally superposed onto the seven bonding patterns along the bottom side of the second protective layer pattern 11b through the first chip main body 7a, the second chip main body 7b, and the adhesive layer 5.

As shown in FIG. 4, the first protective layer pattern 11a illustrated in FIG. 4 defines bonding pads 13a by the bonding patterns. As illustrated in FIG. 4, patterned regions of the bonding patterns of the first protective layer pattern 11a are narrower than remaining un-patterned region of the first protective layer pattern 11a. Likewise, the second protective layer pattern 11b defines bonding pads 13b by the bonding patterns which provide patterned regions narrower than remaining un-patterned region of the second protective layer pattern 11b.

In the first and the second chips 3a and 3b, the narrow patterned regions of the bonding pads 13a of the first and the second protective layer patterns 11a and 11b are comparatively weak in stress against warp while the wide un-patterned regions of the first and the second protective layer patterns 11a and 11b are comparatively strong in stress against warp.

It is to be noted in the illustrated example that the narrow patterned regions and the wide un-patterned regions of the first protective layer pattern 11a are two-dimensionally coincident with those of the second protective layer pattern 11b, respectively, in upper and bottom positions placed on the first and the second protective layer patterns 11a and 11b. Accordingly, it is readily understood that the stress on both the narrow patterned regions and the wide un-patterned region of the first protectively layer pattern 11a is cancelled by the stress on both the narrow patterned regions and the wide un-patterned region of the second protective layer 11b and, as a result, the warp of the first and the second chips 3a and 3b can be completely suppressed by the illustrated back-to-back structure. This makes it possible to improve a quality of the chip structure.

In addition, suppressing such a warp dispenses with a process of flattening a warped chip and brings about simplification of chip manufacturing processes and a reduction of costs. Suppressing the warp enables to manufacture a thinner chip, to cope with further thinner requirements, and to stack more than two chips.

Inasmuch as the first and the second chips 3a and 3b illustrated in FIGS. 2 and 3 have the reflection symmetrical relationship between them, each chip is similar to each other in electrical characteristics, delays, capacities, designing may be made without considering differences of characteristics between them. When a semiconductor memory device is formed by the illustrated chip structure 1 wherein each of the first and the second chips 3a and 3b is a memory chip, such as a DRAM, the chip structure 1 can realize the semiconductor memory device which has twice a memory capacity of each memory chip.

The bonding pads 13a and 13b may be replaced by fuses arranged within fuse windows placed instead of the bonding patterns. With this structure also, the first and the second reflective layer patterns 11a and 11b have the first reflection symmetrical relationship between them. Therefore, it is possible to obtain the back-to-back structure illustrated in FIG. 4.

Now, description will be made about a method of manufacturing the chip structure 1 illustrated in FIGS. 2 to 4.

At first, either one of the first and the second chips 3a and 3b is designed and attains chip data which is related to the designed chip and which specifies two-dimensional configuration of the designed chip. Thereafter, processing is carried out to obtain mirror image data or reflection symmetrical data of the chip data to specify two-dimensional configuration of the remaining one of the chips.

The first and the second chips 3a and 3b are manufactured on the basis of the chip data and the mirror image data. Thereafter, the first and the second chips 3a and 3b are adhered to each other via the adhesive layer 5 on the first and the second back surfaces to form the back-to-back structure illustrated in FIG. 4.

Referring to FIG. 5, a device 1 according to a second embodiment of this invention might be called a semiconductor device or a chip structure and is sealed within a sealing portion 21 together with bonding wires 29. For brevity of description, description would be omitted in connection with the device 1 because the device 1 itself is similar to that illustrated in FIGS. 2 to 4.

More specifically, the illustrated semiconductor device has a substrate (third substrate) 25 with an upper principal surface and a lower principal surface, a plurality of solder balls 27 attached to the lower principal surface, and the sealing portion 21 mounted on a side of the upper principal surface. Practically, the substrate 25 may have internal multi-layer connections which are embedded within an insulation material and which has conductive pads on the upper principal surface, although not shown in FIG. 5. The bonding pads 13a and 13b on the first and the second chip main bodies 7a and 7b are electrically connected to the conductive pads on the upper principal surface of the substrate 25 through the bonding wires 29. At any rate, the bonding pads 13a and 13b are electrically connected to the solder balls 27 through the bonding wires 29, the conductive pads on the upper principal surface of the substrate 25 and internal connections within the substrate 25.

As readily understood from FIG. 5, the illustrated device may be called a semiconductor device of a ball grid array (BGA) type which is encapsulated within a package formed by the substrate 25, the sealing portion 21, and the plurality of the solder balls 27. Such a semiconductor device of the BGA type may be referred to as a semiconductor package also and can be sealed within the package without any warp of the first and the second chips 3a and 3b, as mentioned in conjunction with FIGS. 2 to 4. Specifically, the stress imposed on the first chip 3a is cancelled by the stress imposed on the second chip due to the reflection symmetrical relationship or mirror image relationship between the first and the second protective layer patterns 11a and 11b.

According to the above-mentioned structure, it is possible to thin the semiconductor device, to improve the quality of the semiconductor device, to simplify manufacturing processes, and to reduce costs because the warp of each semiconductor chip 3a and 3b can be suppressed. In addition, the reflection symmetrical relationship of the first and the second chips 3a and 3b makes it possible to realize the same electrical characteristics in the first and the second chips 3a and 3b and to simplify designing of each chip. When each chip 3a and 3b forms a memory device, the illustrated semiconductor device structures a memory device which has twice a memory capacity of each chip.

Although the illustrated semiconductor device is of the BGA type, the semiconductor device may be a semiconductor device of, for example, a pin grid array (PGA) type, a small outline package (SOP) type, or the like.

The semiconductor device of the BGA type shown in FIG. 5 may be manufactured by mounting the chip structure 1 on the substrate 25, by bonding the bonding pads on the first and the second chip main bodies 7a and 7b onto the conductive pads on the substrate 25 through the bonding wires 29, by sealing the first and the second chips 3a and 3b by the sealing portion 21 together with the bonding wires 29, and by mounting the solder balls 27 onto the lower principal surface of the substrate 25.

Thus, it is possible to obtain the semiconductor device which includes the chip structure illustrated in FIGS. 2 to 4 and which forms a packaged semiconductor device.

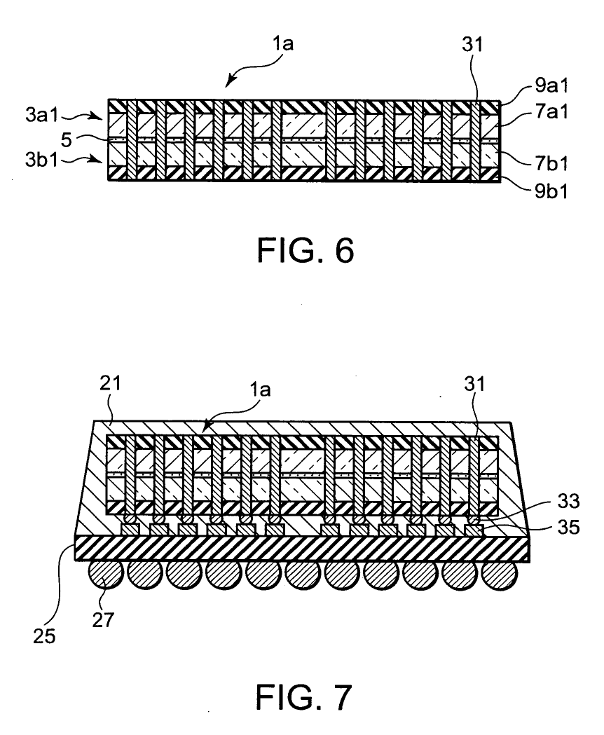

Referring to FIG. 6, a device according to a third embodiment of this invention is structured by a semiconductor device or a chip structure 1a which is formed by a first chip 3a1 and a second chip 3b1 and may therefore be called the chip structure 1a. The illustrated first chip 3a1 has a first chip main body 7a1 and a first protective layer 9a1 while the second chip 3b1 has a second chip main body 7b1 and a second protective layer 9b1. The first protective layer 9a1 of the first chip 3a1 and the second protective layer 9b1 of the second chip 3b1 two-dimensionally have a reflection symmetrical relationship or a mirror image relationship with each other, as mentioned in connection with FIGS. 2 to 4. As shown in FIG. 6, the first chip 3a1 and the second chip 3b1 form a back-to-back structure by attaching a first back surface of the first chip 3a1 to a second back surface of the second chip 3b1 via an adhesive layer 5.

Like in FIGS. 2 to 4, positions of bonding pads and/or fuse windows of the first chip 3a1 are coincident with positions of bonding pads and/or fuse windows of the second chip 3b1 in the illustrated back-to-back structure also.

In the illustrated example, via holes are formed at the respective bonding pads and fuses and are allowed to pass through the first and the second chips 3a1 and 3b1 and via hole conductors 31 are embedded within the respective via holes. In consequence, the bonding pads and the fuses of the first chip 3a1 are interconnected to those of the second chip 3b1.

The chip structure 1a illustrated in FIG. 6 can be easily mounted onto any other substrate or a wiring board.

Referring to FIG. 7, a device according to a fourth embodiment of this invention includes a chip structure 1a illustrated in FIG. 6 and a substrate (third substrate) 25 having an upper principal surface and a lower principal surface directed upwards and downwards of FIG. 7, respectively. On the upper principal surface of the substrate 25, a plurality of connection pads 35 are arranged while solder balls 27 are attached to the lower principal surface of the substrate 25. Although not shown in FIG. 7, the connection pads 35 on the upper principal surface are electrically connected to the solder balls 27 through internal conductive layer or layers included in the substrate 25.

Moreover, the connection pads 35 on the upper principal surface are bonded to the via hole conductors 51 through solder balls 33. As a result, the via hole conductors 51 are electrically connected to the solder balls 27 attached onto the lower principal surface of the substrate 25. The chip structure 1a, the connection pads 35, and the solder balls 33 are sealed by a sealing portion 21, as shown in FIG. 7. Thus, the illustrated semiconductor device forms a semiconductor device of a BGA type or a packaged semiconductor device.

The illustrated semiconductor device can be simply assembled without any bonding wires. Like in FIG. 5, the semiconductor device may be of a PGA type, a SOP type, or the like.

The semiconductor device according to the fourth embodiment of this invention can be manufactured by mounting the solder balls 33 under the via hole conductors 31 of the chip structure 1a and by depositing the connection pads 35 on the upper principal surface of the substrate 25. Subsequently, the solder balls 33 are contacted with the connection pads 35. Thus, the chip structure 1a is mounted onto the substrate 25 and is sealed by the sealing portion 21. Thereafter, the solder balls 25 are mounted onto the lower principal surface of the substrate 25 to obtain the illustrated semiconductor device.

Inasmuch as the semiconductor device according to the fourth embodiment includes the chip structure 1a which is mentioned in detail in connection with FIG. 5, the semiconductor device, the semiconductor device according to the fourth embodiment has advantages similar to those mentioned in connection with FIG. 5 also.

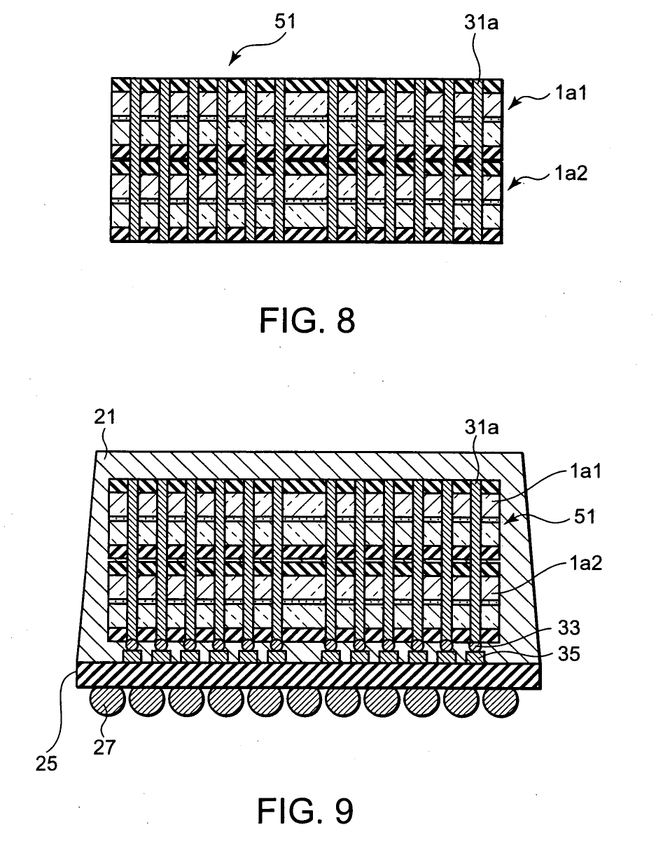

Referring to FIG. 8, a device or a semiconductor according to a fifth embodiment of this invention is featured by a chip stack structure 51 which has first and second chip structures 1a1 and 1a2 each of which has a back-to-back structure similar in structure to the chip structure 1a illustrated in FIG. 6. The chip stack structure 51 is given by stacking the first chip structure 1a1 onto the second chip structure 1a2 in a thickness direction and by electrically connecting both the first and the second chip structures 1a1 and 1a2 through via hole conductors 31a. The via hole conductors 31a are placed at positions of bonding pads and/or fuse windows.

Although two chip structures are stacked in FIG. 8, three or more chip structures can be easily stacked when each chip structure has bonding pads and/or fuse windows placed at the same positions.

Referring to FIG. 9, a device or a semiconductor device according to a sixth embodiment of this invention has the chip stack structure 51 which is illustrated in FIG. 8 and which is sealed within a sealing portion 21, so as to form a semiconductor device of a BGA type. Specifically, the illustrated chip stack structure 51 is mounted on the upper principal surface of the substrate 25 through the solder balls 33 and the connection pads 35 in the manner mentioned in connection with FIG. 7. The connection pads 35 are electrically connected to the solder balls 27 attached on the lower principal surface of the substrate 25, through conductive layer or layers formed within the substrate 25.

The semiconductor device illustrated in FIG. 9 may be assembled in a manner similar to that described about the semiconductor device shown in FIG. 7.

Since each of the first chip structure 1a1 and the second chip structure 1a2 is structured by the first and the second chips having the reflection symmetrical relationship, as mentioned before, it is possible to avoid occurrence of a warp of not only the first and the second chips but also the first and the chip structures 1a1 and 1a2. Accordingly, more than two chip structures can be easily stacked without any warp and can realize a great memory capacity when a semiconductor memory is formed in each chip.

Although this invention has thus far been described in connection with several embodiments thereof, it will be appreciated for those skilled in the art that those embodiments are provided solely for illustrating this invention and should not be relied upon to construe the appended claims in a limiting sense.

What is claimed is:

1. A device, comprising:
a first chip which comprises a first substrate having a first side and a second side opposite to the first side, a plurality of first bonding pads provide on the first side of the first substrate, and a plurality of first via hole conductors each extending from an associated one of the first bonding pads and penetrating the first substrate up to the second side of the first substrate; and
a second chip which comprises a second substrate having a third side and a fourth side opposite to the third side, a plurality of second bonding pads provide on the third side of the second substrate, and a plurality of second via hole conductors each extending from an associated one of the second bonding pads and penetrating the second substrate up to the fourth side of the first substrate, the second bonding pads on the third side of the second substrate being arranged in a mirror symmetry to the first bonding pads on the first side of the first substrate;
portions of the first via hole conductors appearing on the second side of the first substrate of the first chip being connected respectively portions of the second via hole conductors appearing on the fourth side of the second substrate of the second chip.

2. The device as claimed in claim 1, wherein:
the first chip comprises a first protective layer formed on the first side of the first substrate, the first protective layer includes a plurality of first holes, the first holes are provided correspondingly to the first bonding pads; and
the second chip comprises a second protective layer formed on the third side of the second substrate, the second protective layer includes a plurality of second holes, the second holes are provided correspondingly to the first bonding pads.

3. The device as claimed in claim 1, further comprising an adhesive layer intervened between the second side of the first substrate of the first chip and the fourth side of the second substrate of the second chip.

4. The device as claimed in claim 1, further comprising a third substrate which has an upper surface and a lower surface opposed to the upper surface, a plurality of connection pads formed on the upper surface thereof and a plurality of solder balls formed on the lower surface thereof, each of the connection pads being electrically coupled to an associated one of the solder balls, and wherein the first and the second chips are mounted on the upper surface of the third substrate and each of the first via hole conductors is electrically coupled to a corresponding one of the connection pads.

5. The device as claimed in claim 4, further comprising:
a sealing portion which seals the first and the second chips on the upper surface of the third substrate.

6. A device comprising:
a first and second chips each including a front surface and a back surface opposed to the front surface, the first and second chips adhering to each other so that the back surface of the first chip faces the back surface of the second chip;
a first protective layer formed on the front surface of the first chip and including a plurality of first holes;
a second protective layer formed on the front surface of the second chip and including a plurality of second holes, the second holes in the second protective layer being arranged in a mirror symmetry to the first holes in the first protective film; and
a plurality of first via hole conductors each extending from a corresponding one of the first holes to a corresponding one of the second holes through the first and second chips.

7. The device as claimed in claim 6, further comprising an adhesive layer formed between the back surface of the first chip and the back surface of the second chip, and wherein the first via hole conductors penetrate the adhesive layer.

8. The device as claimed in claim 6, further comprising a substrate including a first and second surface, a plurality of connection pads formed on the first surface thereof and a plurality of solder balls formed on the second surface thereof, each of the connection pads being electrically coupled to an associated one of the solder balls, and wherein the first and second chips are mounted on the first surface of the substrate and each of the first via hole conductors is electrically coupled to a corresponding one of the connection pads.

9. The device as claimed in claim 6, further comprising a third and fourth chips each including a front surface and a back surface opposed to the front surface, the third and fourth chips adhering to each other so that the back surface of the third chip faces the back surface of the fourth chip, the first, the second, the third and the fourth chips being stacked so that the front surface of the second chip faces the front surface of the third chip;
a third protective layer formed on the front surface of the third chip and including a plurality of third holes;
a fourth protective layer formed on the front surface of the fourth chip and including a plurality of fourth holes, the fourth holes in the fourth protective layer being arranged in a mirror symmetry to the third holes in the third protective film; and
a plurality of second via hole conductors each extending from a corresponding one of the third holes to a corresponding one of the fourth holes through the third and fourth chips, each of the second via hole conductors being electrically coupled to a corresponding one of the first via hole conductors.
